(19) United States
(12) Patent Application Publication
(10) Pub. No.: US 2024/0276755 A1
(43) Pub. Date: Aug. 15, 2024

(54) CHARGE PRODUCING STRUCTURE AND ORGANIC EL ELEMENT

(71) Applicant: KANEKA CORPORATION, Osaka-shi, Osaka (JP)

(72) Inventors: Kyohei OTSUKI, Kamikita-gun (JP); Shuhei MIURA, Osaka-shi (JP)

(21) Appl. No.: 18/566,015

(22) PCT Filed: May 25, 2022
(86) PCT No.: PCT/JP2022/021333

§ 371 Date: Nov. 30, 2023

(30) Foreign Application Priority Data
Jun. 1, 2021 (JP) 2021-092238

(51) Int. Cl. H10K 50/16; H10K 85/30

(52) U.S. Cl. CPC H10K 50/166; H10K 85/30

(57) ABSTRACT

The present invention provides a charge generation structure and an organic EL element that improve efficiency of charge generation and improve stability thereof as compared with the prior art, and thus have excellent reliability.

The charge generation structure includes a plurality of charge transport layers and a charge transfer material layer, the charge transfer material layer is sandwiched between two charge transport layers so that both surfaces of the charge transfer material layer are in contact with the two charge transport layers. The charge transport layer includes a charge transport material and the charge transfer material layer only includes charge transfer material and has an average film thickness of 0.05 nm or more and 2.0 nm or less.

### TECHNICAL FIELD

The present invention relates to a charge generation structure. Further, the present invention relates to an organic electroluminescent element (hereinafter, also referred to as an organic EL element) including the charge generation structure, the organic electroluminescent element including a plurality of light-emitting units.

### BACKGROUND ART

An organic EL element is a semiconductor element that converts electric energy into light energy, and in recent years, researches have been actively conducted and practical applications have been advanced.

By improving an organic material and the like constituting the organic EL element, a drive voltage of the element is remarkably lowered and luminous efficiency is enhanced.

In order to further increase luminance of the organic EL element, a high electric field is applied to the element to increase a current density.

However, when the current density is increased, amount of generated heat increases, and thus there is a problem that deterioration of the organic material itself constituting the organic EL element is promoted. Therefore, a measure for increasing the luminance without increasing a drive current is required.

On the other hand, Patent Document 1 proposes a method that achieves high luminance of the element by laminating a plurality of light-emitting units of an organic EL element and connecting the light-emitting units in series.

Patent Document 2 describes a laminated organic EL element in which an electrically insulating connection unit containing a metal oxide such as vanadium pentoxide (V₂O₅) is disposed between a plurality of light-emitting units.

Patent Document 3 proposes to use a connection unit using molybdenum trioxide instead of vanadium pentoxide.

In the organic EL element in which a connection unit is disposed between such light-emitting units, when an electric field is applied, the connection unit simultaneously generates holes that can be injected into a hole transport layer disposed on a cathode side and electrons that can be injected into an electron transport layer disposed on an anode side. Therefore, the plurality of light-emitting units act as if they are connected in series via the connection unit.

Such a lamination technique is called Multi-Photon Emission (MPE).

For example, Patent Document 2 discloses that a radical anion-containing layer composed of Alq:Liq/Al is used as a layer on the anode side of the connection unit.

According to Patent Document 2, Li ions in Liq are reduced by a thermally reducing metal such as Al, which acts as a radical anion generation means. Therefore, it is understood that an electron transporting organic substance such as Alq exists in a radical anion state and generates electrons that can be injected into the electron transport layer.

Various forms of the connection unit other than the configuration described above have been proposed, and in any form, the connection unit includes a charge generation structure that generates electrons and/or holes as movable charges.

### PRIOR ART DOCUMENTS

### Patent Documents

Patent Document 1: JP H11-329748 A
Patent Document 2: JP 2003-272860 A
Patent Document 3: JP 2006-24791 A

### DISCLOSURE OF INVENTION

### Technical Problem

In the organic EL element including the connection unit, a stoichiometric ratio of the materials included in the connection unit is important, and when a composition ratio collapses, the connection unit becomes unstable.

In the organic EL element, when a function of the connection unit decreases, the drive voltage increases, leading to a decrease in power efficiency.

The charge generation structure included in a conventional connection unit includes, for example, a layer that uses an electron transport material as a host material, thereby an electron-donating material being doped thereto. However, physical properties thereof greatly vary depending on the composition ratio of a doping material. Therefore, the charge generation structure is likely to cause instability of the connection unit described above.

In order to prevent this, when a layer doped with the electron-donating material is formed, precise control is required so that the composition ratio does not collapse, and it takes time until a film formation rate is stabilized, and there is a problem that the material is lost accordingly.

In view of the above, an object of the present invention is to provide a charge generation structure and an organic EL element that improve efficiency of charge generation for enhancing the stability as compared with the prior art, thereby realizing excellent reliability.

### Solution to Problem

As a result of intensive studies in order to solve the above problems, the present inventor has found that a charge generation structure with the following configuration has high efficiency and high stability as for charge generation as well as excellent reliability, thereafter being completed the present invention.

In other words, one aspect of the present invention is a charge generation structure including a plurality of charge transport layers and a charge transfer material layer, wherein the plurality of charge transport layers includes a first and a second charge transport layers, the charge transfer material layer being sandwiched between the first and the second charge transport layers so that both surfaces of the charge transfer material layer are each in contact with the first charge transport layer or the second charge transport layer, wherein the charge transport layer includes charge transport material, and wherein the charge transfer material layer only includes the charge transfer material and has an average film thickness of 0.05 nm or more and 2.0 nm or less.

This aspect relates to a charge generation structure including a charge transfer material layer that is sandwiched between two charge transport layers so that both surfaces thereof are each in contact with one of the two charge transport layers, where the charge transport layer includes charge transport material, and the charge transfer material layer only includes charge transfer material and has an average film thickness is 0.05 nm or more and 2.0 nm or less.

According to this aspect, the charge transfer material uniformly exists in a film surface, and a charge transfer can be effectively performed in a film thickness direction, so that a charge generation structure having excellent characteristics and high reliability is obtained.

Then, this aspect is a multilayered charge generation structure of a charge transport layer, a charge transfer material layer only including charge transfer material, and a charge transport layer, and one of the features thereof is that “a charge transfer material layer only including charge transfer material” is used as an alternative to a layer in which dopant is doped in the host material described above.

According to this aspect, formation can be performed by a process of depositing only the charge transfer material without performing co-deposition for doping. Therefore, even though the dopant is a material that is difficult to co-deposit or a material that is difficult to deposit by gas flow for transporting the material to a film formation chamber by a gas flow that is a flow of a vapor-containing gas containing material vapor, the charge generation structure can be formed.

In other words, one of the features of the present invention is that it is possible to use a gas flow vapor deposition apparatus that performs such gas flow vapor deposition, and to perform a part of the film formation process by vapor deposition based on an arrival of the material vapor in a vacuum atmosphere caused by a mean free path, instead of gas flow vapor deposition. Further, the charge generation structure of this aspect is preferably manufactured using this vapor deposition method.

In other words, by adopting the charge generation structure of this aspect, by using a film formation apparatus for gas flow film formation (another name: gas carrier film formation), it is possible to deposit a very thin charge transfer material layer in a range of a mean free path while maintaining high material utilization efficiency and productivity as a whole, and a charge generation structure is obtained that is excellent in a charge transfer property and a transport property, and has high reliability, high productivity, and high performance.

According to this aspect, since an average layer thickness of the charge transfer material layer is as thin as 0.05 nm or more and 2.0 nm or less, the excellent charge transfer property of the charge transfer material layer is exhibited, and the transport property of the charge transport layer sandwiching the charge transfer material layer cannot be easily obstructed, thus a charge generation structure with higher performance is formed.

According to this aspect, formation of the charge generation structure can be performed without performing co-deposition as described above. In other words, each layer can be managed only by the film thickness.

Therefore, it can also be formed by a highly productive manufacturing method capable of unifying management items and reducing material loss generated during co-deposition.

As a result, an element including the charge generation structure of this aspect, for example, an organic EL element, realizes high performance, high reliability, and a low cost.

In other words, this aspect has a structure that includes a dopant in a shape of a dopant single layer and further has a specific structure usually considered not to exhibit the transfer property unless doping is performed by co-deposition. It can also be said that this aspect has found that charges can be effectively generated by adopting such a structure.

In other words, the charge generation structure of this aspect can be formed by single-layer film formation of each material, and a rate matching step required during co-deposition is eliminated. As a result, in the charge generation structure of this aspect, the productivity is improved as compared with the prior art, and the charge generation structure can be produced at a low cost because the amount of the material consumed in the rate matching step can be decreased. Furthermore, the charge generation structure of this aspect can be formed using, for example, a gas carrier film formation apparatus.

In a preferred aspect, the charge generation structure includes at least two of the charge transfer material layers, the charge transfer material layers including a first and a second charge transfer material layers, wherein the plurality of charge transport layers include an intermediate charge transport layer sandwiched between the first and the second charge transfer material layers so that both surfaces of the intermediate charge transport layer are each in contact with the first charge transfer material layer or the second charge transfer material layer, and wherein the intermediate charge transport layer only includes charge transport material and has an average film thickness of 0.25 nm or more and 4 nm or less.

This aspect relates to the fact that a charge transport layer that is sandwiched between two charge transfer material layers so that both surfaces thereof are in contact with the charge transfer material layer is included as an intermediate charge transport layer, and the intermediate charge transport layer only includes the charge transport material and has an average film thickness of 0.25 nm or more and 4 nm or less.

According to this aspect, it is a structure in which at least two or more layers of the charge transfer material layer are included, and a thin intermediate charge transport layer is sandwiched between the charge transfer material layers. In other words, this aspect has a structure in which the charge transfer material is periodically dispersed.

Therefore, a charge transfer function of the charge transfer material layer is effectively exhibited, and a charge generation structure having more excellent characteristics, and higher reliability and performance is obtained.

In a preferred aspect, the charge generation structure includes two or more and seven or less of the intermediate charge transport layers.

According to this aspect, since the charge transfer function of the charge transfer material layer is more effectively exhibited, a charge generation structure with further higher performance is obtained.

Further, the charge transport material is preferably an electron transport material.

The electron transport material is preferably one or more selected from the group consisting of quinolinolato-based metal complexes, anthracene-based compounds, oxadiazole-based compounds, triazole-based compounds, phenanthroline-based compounds, and silole-based compounds.

The charge transfer material is preferably an electron-donating material.

The electron-donating material is preferably one or more selected from the group consisting of alkali metals, alkaline earth metals, rare earth metals, compounds of these metals, phthalocyanine complexes containing these metals as a central metal, and dihydroimidazole compounds.

In a preferred aspect, the charge transport material is an electron transport material, the electron transport material is one or more selected from the group consisting of quinolinolato-based metal complexes, anthracene-based compounds, oxadiazole-based compounds, triazole-based compounds, phenanthroline-based compounds, and silole-based compounds, the charge transfer material is an electron-donating material, and the electron-donating material is one or more selected from the group consisting of alkali metals, alkaline earth metals, rare earth metals, compounds of these metals, phthalocyanine complexes containing these metals as a central metal, and dihydroimidazole compounds.

According to this aspect, the charge transfer function of the charge transfer material layer is more effectively exhibited.

For example, when the charge transport material is an electron transport material and the electron-donating material is an electron-donating metal such as an alkali metal, an alkaline earth metal, or a rare earth metal, the charge generation structure of this aspect is preferably a repeated structure of an electron transport material layer/an electron-donating metal layer/an electron transport material layer/ . . . /an electron-donating metal layer/an electron transport material layer.

Such a charge generation structure is preferably provided, for example, on an anode side of a connection unit to be described later in an organic EL element.

In a preferred aspect, the charge transfer material is ytterbium (Yb).

According to this aspect, the charge transfer function of the charge transfer material layer is more effectively exhibited.

One aspect of the present invention is an organic EL element including the charge generation structure described above.

In a preferred aspect, the organic EL element includes: a light-pervious anode layer; a light-emitting functional layer; and

a reflective cathode layer in this order, wherein the light-emitting functional layer includes: a short-wavelength fluorescent light-emitting unit; a connection unit; and a long-wavelength phosphorescent light-emitting unit in an order from the light-pervious anode layer toward the reflective cathode layer, wherein the connection unit injects electrons toward the short-wavelength fluorescence light-emitting unit and injects holes toward the long-wavelength phosphorescence light-emitting unit, and wherein the connection unit includes the charge generation structure.

### Effect of Invention

In the charge generation structure of the present invention, the charge transfer material uniformly exists in the film surface, and the charge transfer can be effectively performed in the film thickness direction, so that the charge generation structure has excellent characteristics and high reliability as compared with the prior art.

### BRIEF DESCRIPTION OF DRAWINGS

FIG. 1 is a cross-sectional view illustrating a configuration of an organic EL element according to an embodiment of the present invention.

FIG. 2 is a cross-sectional view illustrating a charge generation structure according to an embodiment of the present invention.

FIG. 3 is a cross-sectional view illustrating the configuration of the organic EL element in FIG. 1 in more detail.

### BEST MODE FOR CARRYING OUT THE INVENTION

Hereinafter, embodiments of the present invention will be described. (Charge generation structure)

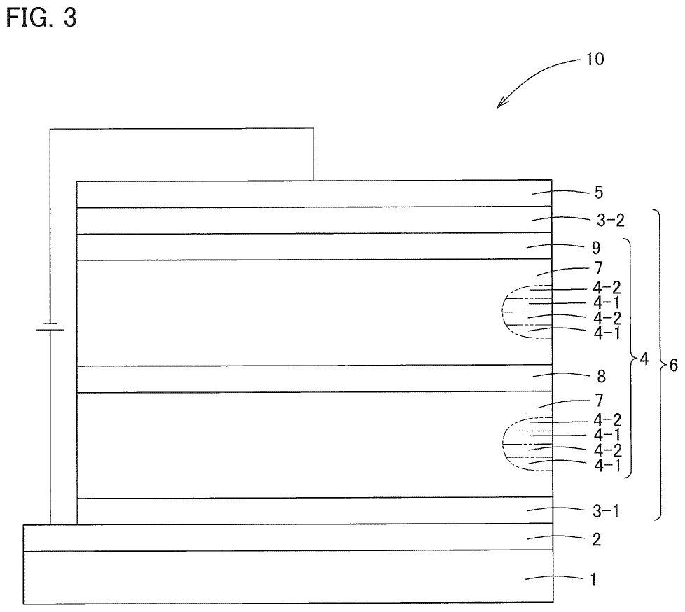

As shown in FIGS. 2 and 3, a charge generation structure 7 of the embodiment of the present invention includes a charge transfer material layer 4-2 that is sandwiched between two charge transport layers 4-1 and 4-1 so that both surfaces thereof are in contact with each other.

The charge transfer material layer 4-2 only includes charge transfer material to be described later.

The charge transfer material layer 4-2 has an average film thickness of 0.05 nm or more and 2.0 nm or less.

The average film thickness of the charge transfer material layer 4-2 is, for example, about 0.2 nm in atomic diameter, which is representative of an electron-donating metal to be described later. As a result, it is considered that the transport property of the charge transport layer 4-1 sandwiching the charge transfer material layer 4-2 is not inhibited while the charge transfer property of the charge transfer material layer 4-2 is maximized.

From a viewpoint of the idea described above, the average film thickness of the charge transfer material layer 4-2 is preferably 1 nm or less, and more preferably 0.5 nm or less.

Within this range, a charge generation structure with higher performance is formed.

As shown in FIGS. 2 and 3, the charge generation structure 7 preferably includes, as an intermediate charge transport layer, a charge transport layer 4-1 that is sandwiched between two charge transfer material layers 4-2 and 4-2 so that both surfaces thereof are in contact with each other.

The intermediate charge transport layer 4-1 sandwiched between the charge transfer material layers 4-2 and 4-2 preferably only contains a charge transport material.

As will be described later, the intermediate charge transport layer 4-1 preferably has an average film thickness of 0.25 nm or more and 4 nm or less.

The charge generation structure 7 preferably includes two or more and seven or less layers of the intermediate charge transport layer 4-1.

Further, in the charge generation structure 7, a number of layers of the charge transfer material layer 4-2 is preferably smaller by one layer than the number of layers of the intermediate charge transport layer 4-1, and more preferably includes one or more and six or less layers.

Since the film thickness of the charge generation structure 7 can be easily controlled, the charge transport layer 4-1 and the charge transfer material layer 4-2 are preferably formed by a vacuum vapor deposition method.

It is preferable that a crucible temperature of a vacuum vapor deposition apparatus used in the vacuum vapor deposition method is stably maintained so that the material is always vaporized at a constant rate.

In the vacuum vapor deposition apparatus used in the vacuum vapor deposition method, it is preferable to control a supply of a vaporized material from a crucible in a stable vaporized state to a film formation surface only by opening and closing a film formation shutter.

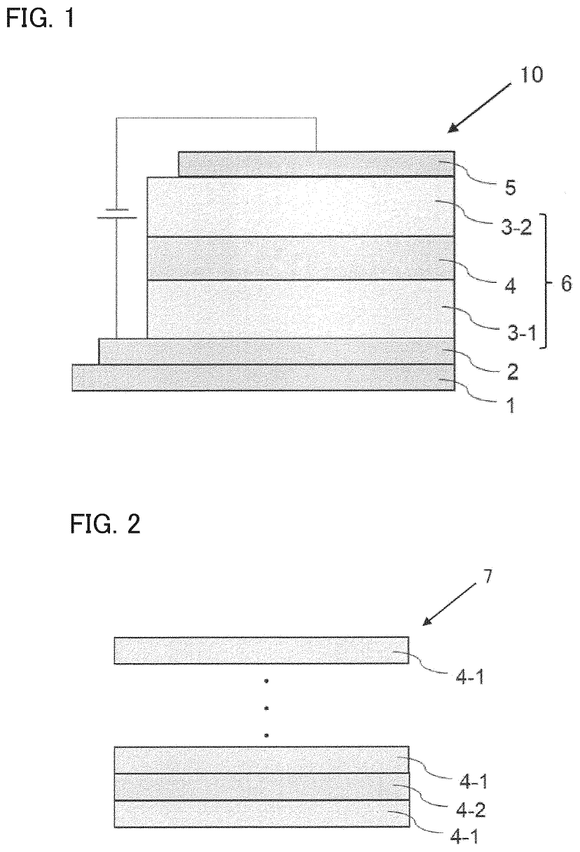

As shown in FIGS. 1 and 3, the connection unit 4 is preferably disposed so as to be in direct contact with a light-emitting unit 3-1.

Further, as shown in FIG. 3, the connection unit 4 can include two charge generation structures 7.

In this case, the connection unit 4 preferably includes a separation layer 8 between the charge generation structure 7 and the charge generation structure 7 for the purpose of improving the reliability of the charge generation structure 7. Further, the connection unit 4 preferably has a blocking layer 9 between the charge generation structure 7 and a light-emitting unit 3-2.

The separation layer 8 and the blocking layer 9 may be the same layer as the charge transport layer 4-1, but among them, it is preferable to be the same layer as the intermediate charge transport layer 4-1 sandwiched between the charge transfer material layers 4-2 and 4-2. The separation layer 8 and the blocking layer 9 are also preferably bipolar transport layers.

An organic material used for the separation layer 8 and the blocking layer 9 is not particularly limited, and any known material can be used.

The organic material used for the separation layer 8 and the blocking layer 9 is preferably an electron transport material so as not to increase the drive voltage in the organic EL element 10 as shown in FIG. 1, for example, from a viewpoint of exhibiting a high charge generation function.

In the blocking layer 9, an HOMO (highest occupied molecular orbital) level of the organic material is preferably shallower than the HOMO level of the organic material used for a hole injection layer in the light-emitting unit 3-2. This is because holes in the hole injection layer are blocked from moving to the separation layer 8.

The blocking layer 9 preferably has an average film thickness of 1 nm or more and 5 nm or less.

When the film thicknesses of the separation layer 8 and the blocking layer 9 are too thick, the function of the connection unit 4 may deteriorate, for example, in the organic EL element 10, the drive voltage becomes large, and when the film thicknesses are too thin, the reliability deteriorates. Therefore, the film thicknesses of the separation layer 8 and the blocking layer 9 are preferably 5 nm or more and 40 nm or less.

### (Charge Transport Layer)

The charge transport layer 4-1 is a layer in which electrons and/or holes are movable in the thickness direction by application of a voltage in a thickness direction of the layer, and a layer in which charges that mainly move are electrons is referred to as an electron transport layer, a layer in which the charges are holes is referred to as a hole transport layer, and a layer in which the charges are both electrons and holes is referred to as a bipolar transport layer.

Such a charge transport layer 4-1 is a layer in which the charge transport material is a main constituent material. The layer may include a material other than the charge transport material, may include a plurality of types of charge transport materials, or may only include a single charge transport material.

The above-described “only include charge transfer material” means “only include a plurality of compounds having the same type of the charge transfer property or a single metal”. Likewise, “only include charge transport material” means “only include a plurality of compounds having the same type of the charge transport property or a single metal”. Preferably both of the two mean “only include a single compound” or “only include a single metal”.

Such a charge transport layer 4-1 is not particularly limited, and any known material can be used.

The average film thickness of the intermediate charge transporting layer 4-1 sandwiched between the charge transfer material layers 4-2 and 4-2 is preferably 0.1 nm or more, and more preferably 0.25 nm or more.

The average film thickness of the intermediate charge transporting layer 4-1 is preferably 5 nm or less, and more preferably 4 nm or less.

As the intermediate charge transporting layer 4-1 is made thinner, the reliability tends to be impaired, and as the intermediate charge transporting layer 4-1 is made thicker, the performance tends to deteriorate, for example, the drive voltage of the organic EL element 10 increases and the luminous efficiency tends to decrease. This is because the charge transfer material diffuses beyond the charge generation structure 7.

All the intermediate charge transporting layers 4-1 may have the same film thickness or different film thicknesses, but the intermediate charge transporting layer 4-1 on the side of a short-wavelength fluorescence light-emitting unit 3-1 is preferably larger in film thickness than the intermediate charge transporting layer 4-1 on the side of a long-wavelength phosphorescent light-emitting unit 3-2.

(Intermediate charge transport layer)

The intermediate charge transport layer 4-1 preferably includes an electron transport material.

The intermediate charge transport layer 4-1 preferably only includes electron transport material, and more preferably only includes a single electron transport material.

The electron transport material is preferably one selected from the group consisting of a quinolinolato-based metal complex, an anthracene-based compound, an oxadiazole-based compound, a triazole-based compound, a phenanthroline-based compound, and a silol-based compound.

### (Charge Transfer Material Layer)

The charge transfer material layer 4-2 preferably only includes charge transfer materials, and more preferably only includes a single charge transfer material.

The charge transfer material layer 4-2 preferably only includes electron-donating material, and more preferably only includes a single electron-donating material.

The electron-donating material is preferably one selected from the group consisting of an alkali metal, an alkaline earth metal, a rare earth metal, a compound of these metals, a phthalocyanine complex containing these metals as a central metal, and a dihydroimidazole compound, and more preferably ytterbium (Yb).

In other words, the material forming the charge transfer material layer 4-2 is preferably an electron-donating material.

When the electron-donating material is in a cationic state, electrons are released, and the released electrons move to an adjacent charge transport layer 4-1.

The electron-donating material preferably contains an electron-donating metal such as an alkali metal, an alkaline earth metal, a rare earth metal, or a compound of these metals.

As the alkali metal, lithium (Li) or the like is suitably used, as the alkaline earth metal, magnesium (Mg), calcium (Ca) or the like is suitably used, and as the rare earth metal, ytterbium (Yb), cerium (Ce) or the like is suitably used.

Further, alloys of these metals with aluminum (Al), silver (Ag), indium (In), or the like are also suitably used.

Among these, in order to prevent diffusion of the electron-donating material in the layer, a metal having a large atomic radius is preferable, and ytterbium (Yb) is particularly preferable.

### (Organic EL Element)

As shown in FIGS. 1 and 3, the organic EL element 10 has a structure in which a light-emitting functional layer 6 is sandwiched between an anode layer 2 and a cathode layer 5, and this structure is generally formed on a substrate 1.

The organic EL element 10 includes a light-pervious anode layer 2, the light-emitting functional layer 6, and a reflective cathode layer 5 in this order on a light-pervious substrate 1.

The light-emitting functional layer 6 includes the light-emitting unit 3-1, the connection unit 4, and the light-emitting unit 3-2 in this order from the side of the light-pervious anode layer 2 toward the side of the reflective cathode layer 5.

Note that, in FIGS. 1 and 3, a configuration including two light-emitting units 3-1 and 3-2 is illustrated, but the organic EL element 10 may have a configuration including three or more light-emitting units 3.

In the configuration including three or more light-emitting units 3, the connection unit 4 is preferably provided between each of two adjacent light-emitting units 3 and 3.

In other words, in the organic EL element 10 having three or more light-emitting units 3, the connection unit 4 is preferably sandwiched between the adjacent light-emitting units 3 and 3. Among these connection units 4, at least one connection unit 4 may have the charge generation structure 7.

### (Substrate 1)

The substrate 1 is not particularly limited, and a known substrate can be used, for example, the substrate 1 is appropriately selected and used from a light-pervious substrate such as glass, a silicon substrate, a flexible film substrate, and the like.

In a case of a bottom emission type organic EL element 10 that extracts light from the side of the substrate 1, a light-pervious substrate is generally used.

In such a light-pervious substrate, a transmittance in a visible light region is preferably 80% or more, and more preferably 95% or more, from a viewpoint of reducing a loss of light radiated to the outside relative to emitted light.

### (Light-Pervious Anode Layer 2)

The light-pervious anode layer 2 is not particularly limited, and a known light-transmissive anode layer can be used.

Examples of the material constituting the light-pervious anode layer 2 include indium tin oxide (ITO), indium zinc oxide (IZO), tin oxide (SnO₂), and zinc oxide (ZnO).

As the material constituting the light-pervious anode layer 2, from a viewpoint of extraction efficiency of light generated from the light-emitting layer and ease of patterning, ITO or IZO having high transparency can be preferably used, and one or more dopants such as aluminum, gallium, silicon, boron, and niobium may be doped as necessary.

From a viewpoint of transparency, the light-pervious anode layer 2 preferably has a transmittance in the visible light region of 70% or more, more preferably 80% or more, and particularly preferably 90% or more.

The light-pervious anode layer 2 can be formed by, for example, a sputtering method, a thermal CVD method, or the like.

### (Light-Emitting Functional Layer 6)

The light-emitting functional layer 6 has a laminated structure in which a plurality of layers are laminated.

The light-emitting functional layer 6 includes the short-wavelength fluorescence light-emitting unit 3-1, the connection unit 4, and the long-wavelength phosphorescent light-emitting unit 3-2.

The method for forming each layer is not particularly limited, and some organic layers can be formed by a method such as a spin coating method in addition to the vacuum vapor deposition method.

Further, a substance used for a hole injection layer, a hole transport layer, a light-emitting layer, an electron transport layer, an electron injection layer, and the like, which are layers to be described later, is not particularly limited, and any known substance can be appropriately used.

Furthermore, the organic material used for the light-emitting layer is not particularly limited, and any known substance can be used.

The light-emitting unit 3 includes at least one light-emitting layer substantially composed of an organic compound, and may further include a hole injection layer, a hole transport layer, an electron injection layer, and an electron transport layer, and generally, the light-emitting layer includes a hole transport layer and the like on the side of the anode layer 2, and the light-emitting layer includes an electron transport layer and the like on the side of the cathode layer 5.

As for the connection unit 4 shown in FIG. 3, the organic EL element 10 preferably has at least one light-emitting layer in which the light-emitting unit 3-1 disposed on the side of the anode layer 2 contains at least one fluorescent light-emitting material having a peak top at 450 nm to 500 nm.

The connection unit 4 of the organic EL element 10 preferably has at least one light-emitting layer in which the light-emitting unit 3-2 disposed on the side of the cathode layer 5 contains at least one phosphorescent light-emitting material having a peak top at 500 to 600 nm, and at least one phosphorescent light-emitting material having a peak top at 600 to 700 nm.

The connection unit 4 injects electrons into the side of the short-wavelength fluorescence light-emitting unit 3-1 and injects holes into the side of the long-wavelength phosphorescent light-emitting unit 3-2.

The connection unit 4 includes the charge generation structure 7 and is sandwiched between two light-emitting units 3-1 and 3-2.

For example, as shown in FIGS. 2 and 3, the charge generation structure 7 has a structure in which the charge transport layer 4-1, the charge transfer material layer 4-2, and the charge transport layer 4-1 are alternately laminated in this order from the side of the light-pervious anode layer 2.

In other words, the charge generation structure 7 is a multilayer structure that is started from the charge transport layer 4-1, laminated alternately and repeatedly with the charge transfer material layer 4-2 and the charge transport layer 4-1, and ended with the charge transport layer 4-1 in the film thickness direction.

### (Cathode Layer 5)

As the material constituting the cathode layer 5, a metal having a small work function, or an alloy or a metal oxide thereof, or the like is preferably used.

Examples of the metal having a small work function include lithium (Li) and the like in the alkali metal, and magnesium (Mg), calcium (Ca) and the like in the alkaline earth metal.

Further, as the material constituting the cathode layer 5, a single metal composed of a rare earth metal or the like, or alloys of these metals and aluminum (Al), indium (In), silver (Ag) or the like can be used.

Further, as an organic layer in contact with the cathode layer 5, an organometallic complex compound containing at least one selected from a group consisting of an alkaline earth metal ion and an alkali metal ion can also be used.

In this case, as the cathode layer 5, it is preferable to use a metal capable of reducing metal ions of the complex compound to a metal in vacuum, for example, aluminum (Al), zirconium (Zr), titanium (Ti), silicon (Si), or the like, or an alloy containing these metals.

In the embodiment described above, the connection unit 4 has the blocking layer 9 between the charge generation structure 7 and the light-emitting unit 3-2, but the present invention is not limited thereto. The blocking layer 9 may not be provided between the charge generation structure 7 and the light-emitting unit 3-2.

In the embodiment described above, the connection unit 4 has the separation layer 8 between the charge generation structure 7 and the charge generation structure 7, but the present invention is not limited thereto. The separation layer 8 may not be provided between the charge generation structure 7 and the charge generation structure 7.

In the embodiment described above, the connection unit 4 includes two charge generation structures 7, but the present invention is not limited thereto. The connection unit 4 may include one charge generation structure 7 or three or more charge generation structures 7.

In the embodiment described above, the charge generation structure 7 includes two or more and seven or less layers of the intermediate charge transporting layer 4-1, but the present invention is not limited thereto. The charge generation structure 7 may include eight or more layers.

In the embodiment described above, each component member can be freely replaced or added between the embodiments as long as it is included in the technical scope of the present invention.

### EXAMPLE

The present invention will be specifically described with reference to an example.

### Example

In order to confirm operations of the charge generation structure of the present invention, an organic EL element having a connection unit including the charge generation structure was prepared, and current-voltage measurement was performed.

Specifically, on a glass substrate on which an ITO film (film thickness: 120 nm) as a patterned light-pervious anode layer was formed, a bottom emission type organic EL element having a light-emitting region of 80 mm×80 mm was prepared.

First, a short-wavelength fluorescence light-emitting unit was formed on the ITO light-pervious anode layer.

Specifically, first, as a hole injection layer, an organic material having hole transport performance and an electron-accepting material were formed in a film thickness of 14 nm on the ITO light-pervious anode layer by a vacuum vapor deposition method.

Next, as a hole transport layer, an organic material having hole transport performance was formed in a film thickness of 195 nm by the vacuum vapor deposition method.

Next, as a light-emitting layer, an organic material having electron transport performance and a fluorescent organic material having a peak top at 450 to 500 nm were formed in a film thickness of 20 nm by the vacuum vapor deposition method.

Next, as an electron transport layer, an organic material having electron transport performance was formed in a film thickness of 30 nm by the vacuum vapor deposition method.

Subsequently, a connection unit was formed on the short-wavelength fluorescence light-emitting unit.

Specifically, a connection unit including a charge generation structure and a blocking layer was formed on the electron transport layer in this order.

Specifically, as the charge generation structure, an electron transport material A was formed in a film thickness of 4.5 nm as a charge transport layer, an electron-donating material was formed in a film thickness of 0.1 nm as a charge transfer material layer, and an electron transport material B was formed in a film thickness of 0.5 nm as a charge transport layer in this order by the vacuum vapor deposition method. Subsequently, an electron transport material was formed as a blocking layer in a thickness of 3 nm by the vacuum vapor deposition method.

Subsequently, a long-wavelength phosphorescent light-emitting unit was formed on the connection unit.

Specifically, as a hole injection layer, an organic material having hole transport performance, and an electron-accepting material were formed in a film thickness of 12 nm on the connection unit by the vacuum vapor deposition method.

Next, as a hole transport layer, an organic material having hole transport performance was formed in a film thickness of 30 nm by the vacuum vapor deposition method.

Next, as a light-emitting layer, an organic material having electron transport performance, a phosphorescent organic material having a peak top at 500 to 600 nm, and a phosphorescent material having a peak top at 600 to 700 nm were formed in a film thickness of 10 nm by the vacuum vapor deposition method.

Next, as an electron transport layer, an organic material having electron transport performance was formed in a film thickness of 7.5 nm by the vacuum vapor deposition method.

Next, as an electron transport layer, an organic material having electron transport performance different from that described above was formed in a film thickness of 63 nm by the vacuum vapor deposition method.

Next, Li was formed in a film thickness of 0.4 nm by the vacuum vapor deposition method as an electron injection layer.

Subsequently, Ag was formed as a cathode on the long-wavelength phosphorescent light-emitting unit in a film thickness of 120 nm by the vacuum vapor deposition method.

After the organic EL element of the example was formed in this way, a sealing film was formed in a region covering an entire surface of the element by a CVD method.

For the organic EL element of the example thus prepared, a luminance retention ratio showed a good value of 81.6% when a current having a current density of 5.7 mA/cm² was continuously applied for 500 hours under the conditions of a temperature of 85° C. and a humidity of 85%.

### EXPLANATION OF REFERENCE CHARACTERS

1: light-pervious substrate
2: light-pervious anode layer
3: light-emitting unit
3-1: short-wavelength fluorescence light-emitting unit
3-2: long-wavelength phosphorescent light-emitting unit
4: connection unit
4-1: intermediate charge transport layer
4-2: charge transfer material layer
5: cathode layer
6: light-emitting functional layer
7: charge generation structure
8: separation layer
9: blocking layer
10: organic EL element

1. A charge generation structure comprising a plurality of charge transport layers and a charge transfer material layer,
wherein the plurality of charge transport layers includes a first and a second charge transport layers, the charge transfer material layer being sandwiched between the first and the second charge transport layers so that both surfaces of the charge transfer material layer are each in contact with the first charge transport layer or the second charge transport layer,
wherein the charge transport layer includes charge transport material, and
wherein the charge transfer material layer only includes charge transfer material and has an average film thickness of 0.05 nm or more and 2.0 nm or less.

2. The charge generation structure according to claim 1, comprising at least two of the charge transfer material layers, the charge transfer material layers including a first and a second charge transfer material layers,
wherein the plurality of charge transport layers include an intermediate charge transport layer sandwiched between the first and the second charge transfer material layers so that both surfaces of the intermediate charge transport layer are each in contact with the first charge transfer material layer or the second charge transfer material layer, and
wherein the intermediate charge transport layer only includes charge transport material and has an average film thickness of 0.25 nm or more and 4 nm or less.

3. The charge generation structure according to claim 2, comprising two or more and seven or less of the intermediate charge transport layers.

4. The charge generation structure according to claim 1,
wherein the charge transport material is an electron transport material,
the electron transport material being one or more selected from the group consisting of quinolinolato-based metal complexes, anthracene-based compounds, oxadiazole-based compounds, triazole-based compounds, phenanthroline-based compounds, and silole-based compounds, and
wherein the charge transfer material is an electron-donating material,
the electron-donating material being one or more selected from the group consisting of alkali metals, alkaline earth metals, rare earth metals, compounds of these metals, phthalocyanine complexes containing these metals as a central metal, and dihydroimidazole compounds.

5. The charge generation structure according to claim 1, wherein the charge transfer material is ytterbium.

6. An organic EL element comprising the charge generation structure according to claim 1.

7. The organic EL element according to claim 6, comprising: a light-pervious anode layer; a light-emitting functional layer; and a reflective cathode layer in this order,
wherein the light-emitting functional layer includes: a short-wavelength fluorescent light-emitting unit; a connection unit; and a long-wavelength phosphorescent light-emitting unit in an order from the light-pervious anode layer toward the reflective cathode layer,
wherein the connection unit injects electrons toward the short-wavelength fluorescence light-emitting unit and injects holes toward the long-wavelength phosphorescence light-emitting unit, and
wherein the connection unit includes the charge generation structure.
